(19) United States
(12) Patent Application Publication
(10) Pub. No.: US 2010/0167538 A1
(43) Pub. Date: Jul. 1, 2010

(54) METHOD FOR REMOVING NATIVE OXIDE REMAINING ON A SURFACE OF A SEMICONDUCTOR DEVICE DURING MANUFACTURING

(76) Inventor: Jun Ki KIM, Seoul (KR)

Correspondence Address: LADAS & PARRY LLP, 224 SOUTH MICHIGAN AVENUE, SUITE 1600, CHICAGO, IL, 60604, US

(21) Appl. No.: 12/470,069

(22) Filed: May 21, 2009

(30) Foreign Application Priority Data
Dec. 30, 2008 (KR) 10-2008-0137346

(51) Int. Cl. H01L 21/768

(52) U.S. Cl. 438/675; 257/E21.586

(57) ABSTRACT

A method for removing native oxide that remains on a surface of a semiconductor device is presented. The manufacturing method includes the steps of placing, supplying, moving, and annealing. The placing step includes placing a semiconductor substrate into a first process chamber. The supplying step includes supplying an etchant gas that reacts with the native oxide when the first process chamber is purged and sealed away from air. The moving step includes moving the semiconductor substrate with the byproduct formed on it into a second process chamber in which the moving step can be exposed to air. The annealing the semiconductor substrate in the second process chamber removes the byproduct.

### CROSS-REFERENCE TO RELATED APPLICATIONS

The present application claims priority to Korean patent application number 10-2008-0137346 filed on Dec. 30, 2008, which is incorporated herein by reference in its entirety.

### BACKGROUND OF THE INVENTION

The present invention relates to a method for manufacturing a semiconductor device, and more particularly, to a method for manufacturing a semiconductor device which can minimize the contamination of a semiconductor substrate by effectively removing native oxide that remains on the surface, thereby realizing a decrease in contact resistance and an improvement in the characteristics and the reliability of the resultant semiconductor device.

In general, in a semiconductor device, contact plugs are formed to electrically connect together a lower conductive layer including the junction areas of a semiconductor substrate with an upper conductive layer. Before forming the contact plugs, a cleaning process is usually conducted for the semiconductor substrate which includes cleaning the surfaces of contact holes for contact plugs. The cleaning process is conducted to remove various impurities, including a surface film such as a native oxide, which can remain on the surfaces of the contact holes and on the semiconductor substrate. This cleaning process for removing the native oxide remaining on the surface of the semiconductor substrate is regarded as an important factor that determines the quality of the resultant semiconductor device.

As the high integration of a semiconductor device proceeds, the aspect ratio of the contact holes for contact plugs increases and the narrowness of these contact holes decreases. As a result, it is becoming more and more difficult for a liquid phase chemical solution to thoroughly and completely penetrate within these ever diminutive structures. It is thought that this is because of the surface tension of these liquid phase chemical solutions hinders complete contact during the cleaning process. As a result, the insides of these diminutive contact holes are prone to be improperly cleaned.

Under these situations, a method of implementing the cleaning process as a dry cleaning process using an etchant gas has been proposed in the art. It is thought that the dry cleaning process provides a number of advantages over liquid phase cleaning processes. In particular, contaminations that are brought about by chemical solvents can be prevented. Also, a dry cleaning process does not require a drying process. Further, a dry cleaning process, i.e., a gaseous phase cleaning process, uses an etchant gas that can effectively and more thoroughly reach and penetrate into these extremely diminutive finely resolved niches constructed at the surface of the semiconductor substrate. Because of these and other reasons, the dry cleaning process has been widely adopted in the manufacture of a semiconductor device.

However, in the conventional dry cleaning process that removes native oxide from the semiconductor substrate, the semiconductor substrate should or even must be moved to deposition equipment for forming a conductive layer for contact plugs. This moving process can result in air exposure to the semiconductor substrate. As a result the surface of the semiconductor substrate is likely to be again contaminated with a slight native oxide which results in compromising the contacts by increasing the contact resistances.

In detail, in the conventional art described above, after the native oxide remaining on the surfaces of the contact holes is removed from the semiconductor substrate by using dry cleaning processes in a process chamber of cleaning equipment, the semiconductor substrate is then moved into a process chamber of the deposition equipment for forming a conductive layer for contact plugs. At this time, while the semiconductor substrate is moved, as a result the semiconductor substrate is exposed to air, and as a consequence the surfaces of the contact holes and the semiconductor substrate are likely to be contaminated again which results in increasing the resultant contact resistances.

FIG. 1 is a graph showing contact resistance in the case where a semiconductor substrate is exposed to air (see the reference symbol A) and in the case where the semiconductor substrate is not exposed to air (see the reference symbol B), after a cleaning process is conducted. In the case A where a semiconductor substrate is exposed to air after the cleaning process, contamination of the surfaces of the contact holes and on the semiconductor substrate arises as a result of being exposed to air and the resultant contact resistance increases relative to the case B where a semiconductor substrate is not exposed to air after the cleaning process.

Hence, in the conventional art the semiconductor substrate is moved into the process chamber of the deposition equipment after the native oxide having already been removed from the semiconductor substrate. This moving results in exposing the semiconductor to air, and as a result the surfaces of the contact holes and the semiconductor substrate are prone to being recontaminated with yet another native oxide which in turn compromises that the resultant contact. As a result, in using the conventional art as described above, the characteristics and the reliability of a semiconductor device are likely to deteriorate.

### BRIEF SUMMARY OF THE INVENTION

An embodiment of the present invention is directed to a method for manufacturing a semiconductor device that can minimize the contamination of a semiconductor substrate when removing native oxide from the surface of the semiconductor substrate. Thereby a semiconductor device made from this method can realize a decreased contact resistance.

Also, an embodiment of the present invention is directed to a method for manufacturing a semiconductor device that can realize improved characteristics and the reliability of a resultant semiconductor device.

In one aspect of the present invention, a method for manufacturing a semiconductor device comprises the steps of placing a semiconductor substrate in a first process chamber; supplying an etchant gas into the first process chamber and substantially removing a large portion of a native oxide remaining on the surface of the semiconductor substrate by forming a byproduct on a surface of the semiconductor substrate by reacting the native oxide with the etchant gas while placed in the first process chamber; moving the semiconductor substrate having the byproduct formed on it into a second process chamber; and annealing the semiconductor substrate in the second process chamber to remove the byproduct from the semiconductor substrate.

Before the step of placing the semiconductor substrate in the first process chamber, the method may further comprise the steps of forming an insulation layer on the semiconductor substrate; and defining contact holes by etching the insulation layer.

The first process chamber comprises a process chamber of cleaning equipment.

The etchant gas includes at least one of an N₂ gas, an H₂ gas, an NH₃ gas, an NF₃ gas, an HF gas, an NH₄F gas and gaseous admixtures thereof.

The forming the byproduct on the surface of the semiconductor substrate is implemented at a temperature of about 10˜50° C.

The byproduct comprises (NH₄)₂SiF₆.

The second process chamber comprises a process chamber of deposition equipment.

The annealing step is implemented at a temperature of about 100˜500° C.

The annealing step is implemented using an annealing apparatus of the second process chamber.

After removing the byproduct from the semiconductor substrate, the method further may comprise the step of forming a conductive layer onto the semiconductor substrate.

The step of removing the byproduct and the step of forming the conductive layer are implemented such that the semiconductor substrate is not exposed to air.

The conductive layer comprises a conductive layer for contact plugs.

The method may further comprise the steps of moving the semiconductor substrate having the byproduct removed into a third process chamber; and forming a conductive layer on the semiconductor substrate in the third process chamber.

The third process chamber comprises a process chamber of deposition equipment.

The step of moving the semiconductor substrate into the third process chamber and the step of forming the conductive layer are implemented such that the semiconductor substrate is not exposed to air.

The conductive layer comprises a conductive layer for contact plugs.

The step of moving the semiconductor substrate formed with the byproduct into the second process chamber is implemented such that the semiconductor substrate formed with the byproduct is exposed to air.

### BRIEF DESCRIPTION OF THE DRAWINGS

FIG. 1 is a graph showing contact resistance in the cases where a semiconductor substrate is exposed to air and is not exposed to air after a cleaning process is conducted.

FIGS. 2A through 2E are sectional views illustrating the processes of a method for manufacturing a semiconductor device in accordance with an embodiment of the present invention.

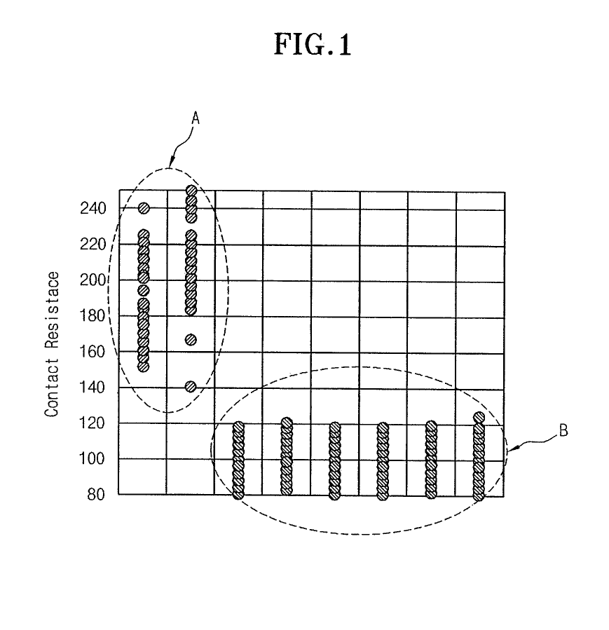

### DESCRIPTION OF SPECIFIC EMBODIMENT

Hereafter, a specific embodiment of the present invention will be described in detail with reference to the attached drawings. The drawings are not necessarily to scale and in some instances proportions may have been exaggerated in order to more clearly depict certain features of the invention.

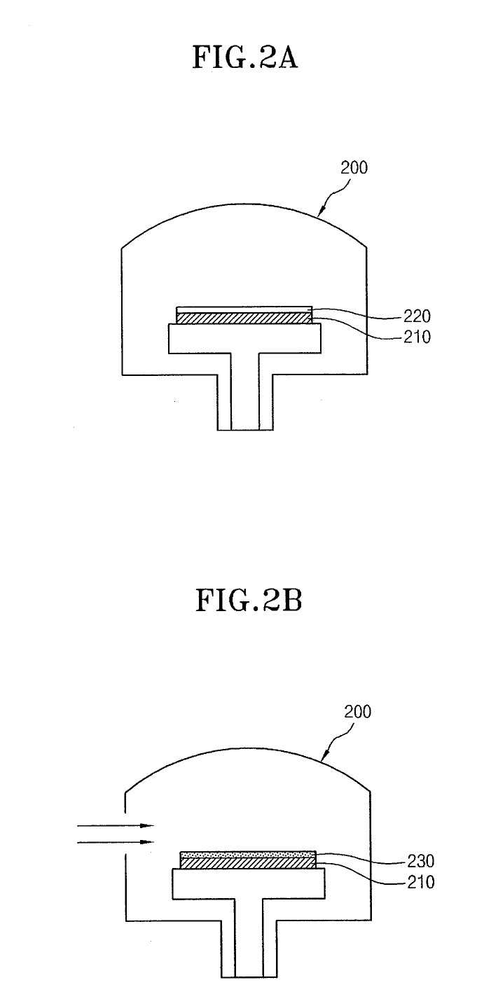

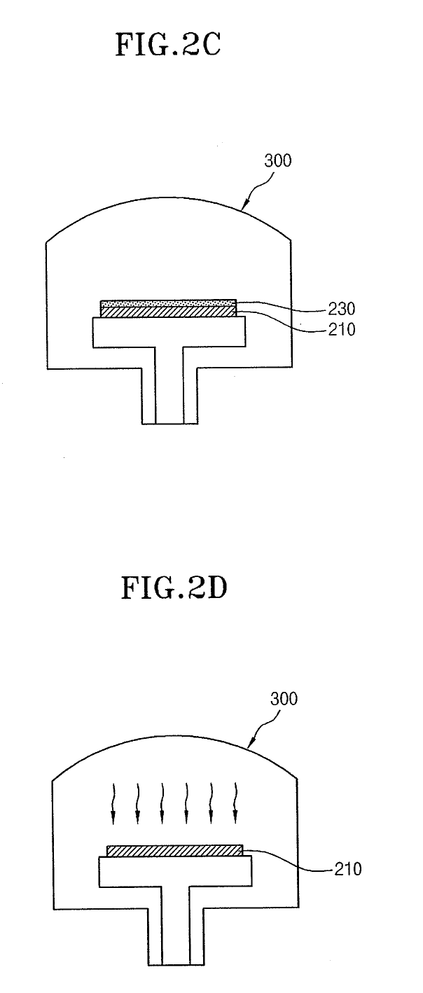

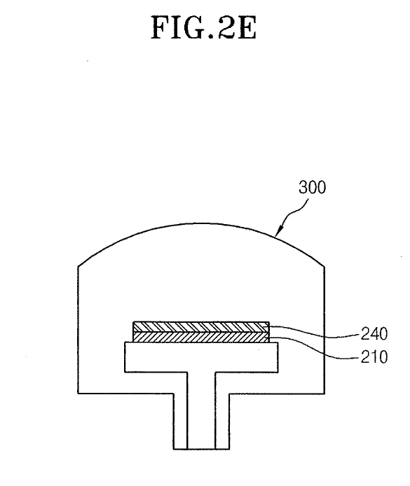

FIGS. 2A through 2E are sectional views illustrating the processes of a method for manufacturing a semiconductor device in accordance with an embodiment of the present invention.

Referring now to FIG. 2A, a semiconductor substrate 210 is placed in a first process chamber 200, for example, the process chamber of cleaning equipment. Here, before placing the semiconductor substrate 210 in the first process chamber 200, processes for forming an insulation layer on the semiconductor substrate 210 and defining contact holes by etching the insulation layer can be conducted. The semiconductor substrate 210 is placed in the first process chamber 200 in the state in which a surface film 220 such as a native oxide surface film 220 remains thereon.

Referring to FIG. 2B, an etchant gas is supplied into the first process chamber 200 in which the semiconductor substrate 210 is placed. The etchant gas is selected from the group consisting of at least one of an N₂, H₂, NH₃, NF₃, HF, NH₄F and gaseous admixtures thereof. By doing this, the native oxide surface film 220 remaining on the surface of the semiconductor substrate 210 reacts with the etchant gas to form a byproduct 230 on the surface of the semiconductor substrate 210.

The one embodiment of the procedure in which the byproduct 230 is formed will be described in detail with reference to the reaction formula 1 given below. First, the etchant gas is supplied into the first process chamber 200 in which the semiconductor substrate 210 is placed, and an NH₄F gas is produced through the reaction of the etchant gas. As the NH₄F gas and the native oxide surface film 220 on the semiconductor substrate 210 react with each other, a (NH₄)₂SiF₆ byproduct 230 is produced. The reaction for forming the byproduct 230 from the native oxide surface film 220 can be performed at any temperature in which it is preferable that it is implemented at a temperature of about 10˜50° C.

NH₄F(g)+SiO₂(s)→(NH₄)₂SiF₆(s)+H₂O(g) [Reaction Formula 1]

Referring to FIG. 2C, the semiconductor substrate 210 having the formed byproduct 230 is subsequently moved into a second process chamber 300. The second process chamber 300 comprises, for example, the process chamber of deposition equipment for subsequently depositing a conductive layer onto the semiconductor substrate 210. Meanwhile, the semiconductor substrate 210 having the byproduct 230 formed on it can be moved into the second process chamber 300 while being exposed to air.

Referring to FIG. 2D, the byproduct 230 is removed from the semiconductor substrate 210 during an annealing step that is performed in the second process chamber 300. The annealing can be performed in the second process chamber 300 at any temperature greater than about 100° C., preferably at a temperature of between about 100˜500° C.

The procedure in which the byproduct 230 is removed through annealing will be described in detail with reference to the reaction formula 2 given below. By heating and vaporizing the byproduct 230, that is, the (NH₄)₂SiF₆ byproduct 230, at a temperature greater than 100° C., the native oxide remaining on the Is surface of the semiconductor substrate 210 along with the byproduct 230 is substantially removed.

(NH₄)₂SiF₆(s)→SiF₄(g)+NH₃(g)+HF(g) [Reaction Formula 2]

Referring now to FIG. 2E, a conductive layer 240, for example, a conductive layer for establishing contact plugs, can then be subsequently formed on the semiconductor substrate 210 after having the byproduct 230 removed from the semiconductor substrate 210. Depositing this conductive layer 240 can be performed within the second process chamber 300 without changing into a different process chamber. By doing this, the conductive layer 240 can be deposited on the semiconductor substrate 210 is a relatively pristine state having little or no native oxide 220 or byproduct 230 because the semiconductor substrate 210 was not exposed to air during the annealing and deposition steps. Therefore, the present method can realize a significant reduction in the amount of contamination of the semiconductor substrate 210.

Meanwhile, although not shown in a drawing, in another embodiment of the present invention, it is envisioned that, after the removing with the byproduct 230 from the semiconductor substrate 210, the semiconductor substrate 210 is moved into a third process chamber and a conductive layer 240 can be subsequently formed onto the semiconductor substrate 210 in the third process chamber. In this case, the procedure for moving the semiconductor substrate 210 removed with the byproduct 230 to the third process chamber and the procedure for forming the conductive layer 240 are preferably implemented so that the semiconductor substrate 210 is not exposed to air. Accordingly, even in another embodiment of the present invention, the semiconductor substrate 210 is not exposed to air after the byproduct 230 is removed and thus the amount of contaminants is minimized which enhances the conductivity of the resultant contact plugs.

Thereafter, while not shown in a drawing, by sequentially conducting a series of well-known subsequent processes, the manufacture of a semiconductor device according to the embodiment of the present invention is completed.

As is apparent from the above description, in the present invention, unlike the conventional art in which, after a native oxide on the surface of the semiconductor substrate is removed in the process chamber of cleaning equipment, the semiconductor substrate is moved into the process chamber for depositing a conductive layer. The present invention teaches how to remove a native oxide on a semiconductor substrate by reacting the native oxide with an etchant gas in the process chamber to form a byproduct on the semiconductor substrate. The semiconductor substrate having the byproduct formed on it is then moved into the process chamber of deposition equipment. Then, after the byproduct is removed, a conductive layer is formed without exposing the semiconductor substrate to air.

Through this, in the present invention, after the semiconductor substrate is moved into the process chamber of the deposition equipment and the native oxide on the surface thereof is removed, the conductive layer is formed with the semiconductor substrate not exposed to air. Therefore, it is possible to prevent the semiconductor substrate from being exposed to air after the native oxide and the byproduct on the surface of the semiconductor substrate have been removed. Accordingly, in the present invention, after the native oxide and the byproduct have been removed and before the conductive layer is formed, the semiconductor substrate is prevented from being exposed to air. Thus, the contamination of the semiconductor substrate brought about by exposure to air of the now pristine surface of the semiconductor substrate can be minimized.

Hence, in the present invention, it is possible to prevent contact resistance from increasing due to the contamination of the semiconductor substrate. Thus, the contact resistance can be effectively decreased, whereby the characteristics and the reliability of a semiconductor device can be improved.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A method for manufacturing a semiconductor device, comprising the steps of:
placing into a first process chamber a semiconductor substrate having a native oxide remaining on a surface of the semiconductor substrate;
supplying an etchant gas into the first process chamber to react with the native oxide remaining on the surface of the semiconductor substrate to substantially remove the native oxide by forming a byproduct on the surface of the semiconductor substrate;
moving the semiconductor substrate formed with the byproduct into a second process chamber; and
annealing the semiconductor substrate in the second process chamber to substantially remove the byproduct away from the surface of the semiconductor substrate.

2. The method according to claim 1 further comprises the steps of:
forming an insulation layer on the semiconductor substrate; and
defining contact holes by etching the insulation layer, wherein the steps of forming and defining are performed before the step of placing the semiconductor substrate in the first process chamber.

3. The method according to claim 1, wherein the first process chamber comprises a process chamber of cleaning equipment.

4. The method according to claim 1, wherein the etchant gas includes at least one of an N₂, H₂, NH₃, NF₃, HF, NH₄F, and gaseous admixtures thereof.

5. The method according to claim 1, wherein forming the byproduct on the surface of the semiconductor substrate is implemented at a temperature of about 10˜50° C.

6. The method according to claim 1, wherein the byproduct comprises (NH₄)₂SiF₆.

7. The method according to claim 1, wherein the second process chamber comprises a process chamber of deposition equipment.

8. The method according to claim 1, wherein the annealing step is implemented at a temperature of about 100˜500° C.

9. The method according to claim 1, wherein the annealing step is implemented using an annealing apparatus of the second process chamber.

10. The method according to claim 1 further comprises the step of forming a conductive layer onto the semiconductor substrate in which the byproduct has been previously removed from the semiconductor substrate.

11. The method according to claim 10, wherein the steps of supplying, moving, annealing, and forming are implemented without exposing the semiconductor substrate to air.

12. The method according to claim 10, wherein the conductive layer comprises a conductive layer for contact plugs.

13. The method according to claim 1 further comprises the steps of:
moving the semiconductor substrate into a third process chamber; and
forming a conductive layer on the semiconductor substrate while in the third process chamber, wherein the steps of moving and forming are performed only after the annealing step that removes the byproduct from the semiconductor substrate.

14. The method according to claim 13, wherein the third process chamber comprises a process chamber of deposition equipment.

15. The method according to claim 13, wherein the steps of moving and forming are implemented such that the semiconductor substrate having the byproduct removed is not exposed to air.

16. The method according to claim 13, wherein the conductive layer comprises a conductive layer for contact plugs.

17. The method according to claim 1, wherein the step of moving is implemented such that the semiconductor substrate formed with the byproduct is exposed to air.
